(19) United States
(12) Patent Application Publication
(10) Pub. No.: US 2023/0217667 A1
(43) Pub. Date: Jul. 6, 2023

(54) ORGANIC LIGHT EMITTING DIODE AND MANUFACTURING METHOD THEREOF, DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventor: Jibum YANG, Beijing (CN)

(21) Appl. No.: 17/927,715

(22) PCT Filed: Oct. 11, 2021
(86) PCT No.: PCT/CN2021/123067

§ 371 Date: Nov. 24, 2022

(30) Foreign Application Priority Data
Nov. 11, 2020 (CN) 202011255722.3

(51) Int. Cl. H10K 50/12; H10K 59/10; H10K 85/60; H10K 85/30

(52) U.S. Cl. CPC H10K 50/12; H10K 59/10; H10K 85/6572; H10K 85/6574; H10K 85/6576; H10K 85/654; H10K 85/658; H10K 85/342

(57) ABSTRACT

An organic light-emitting diode and a preparation method therefore, a display panel and a display device. The organic light-emitting diode comprises an anode (300); a light-emitting layer (200); and a cathode (100), wherein the light-emitting layer (200) is internally provided with a doping material and at least two types of host materials, and a horizontal alignment factor of the light-emitting layer (200) is not less than 65%.

### TECHNICAL FIELD

This disclosure relates to display technology, in particular, to flexible display devices, as well as organic light emitting diodes and manufacturing methods thereof, display panels and display devices.

### BACKGROUND

Organic electroluminescent (OLED) display devices have attracted much attention and are increasingly used in display devices due to their self-luminous, wide viewing angle, high contrast and flexible display. Materials of a light-emitting layer of a conventional organic light-emitting diode are mainly classified into fluorescent materials and phosphorescent materials. Theoretically, the fluorescent material has an internal quantum efficiency of 25% and the phosphorescent material has an internal quantum efficiency of 100%. Therefore, the phosphorescent materials with higher luminous efficiency are mainly applied to OLED products. To further improve the luminous efficiency of the organic light emitting diode, a solution using two or more mixed materials for the light emitting layer has also been proposed. In a case where the light emitting layer is formed by using the mixed materials, light emitting characteristics of the OLED device can be improved by selecting hole transporting and electron transporting characteristics of differ rent materials and controlling energy level parameters such as HOMO, LUMO or T1 of the light emitting layer.

However, the conventional organic light emitting diodes and manufacturing methods thereof, display panels and display devices need to be improved.

### SUMMARY

The present disclosure is directed at least to mitigating or solving at least one of the above-mentioned problems to some extent.

In one aspect of the present disclosure, the present disclosure proposes an organic light emitting diode comprising an anode, a light-emitting layer and a cathode, wherein the light emitting layer has a dopant material and at least two types of host materials therein, and the light emitting layer has a horizontal alignment factor not less than 65%. Thereby, the organic light emitting diode may have higher external quantum efficiency.

According to embodiments of the present disclosure, the host material comprises a hole transporting host material and an electron transporting host material, and each of the hole transporting host material and the electron transporting host material has a horizontal alignment factor not less than 65%. Thereby, the external quantum efficiency of the organic light emitting diode may be further improved.

According to embodiments of the present disclosure, the host material is an organic semiconductor material. Thereby, the performance of the organic light emitting diode can be further improved.

According to embodiments of the present disclosure, the host material comprises at least one selected from Carbazole, Dibenzo furan, Dibenzo Thiophene, Indenlocarbazole, Indocarbazole, Benzofurazarbazole, Benzothiophene, Acridine, Tris-Indolobenzene, and derivatives and thickens thereof. Thereby, the performance of the organic light emitting diode can be further improved.

According to embodiments of the present disclosure, the light emitting layer further comprises an acceptor material comprising at least one selected from Carbazole, Dibenzo furan, Dibenzo Thiophene, Indenlocarbazole, Indocarbazole, Benzofurazarbazole, Benzothiophene, Acridine, Tris-Indolobenzene, and derivatives and thickens thereof. Thereby, the performance of the organic light emitting diode can be further improved.

According to embodiments of the present disclosure, the light emitting layer comprises two types of host materials, and a volume ratio of the two types of host materials is 9:1 to 1:9. Thereby, the performance of the organic light emitting diode can be further improved.

According to embodiments of the present disclosure, the first host material is Indenlocarbazole triazine and the second host material is Bicarbazole. Thereby, the performance of the organic light emitting diode can be further improved.

According to embodiments of the present disclosure, a volume ratio of the first host material to the second host material in the light emitting layer is 1:1. Thereby, the performance of the organic light emitting diode can be further improved.

According to embodiments of the present disclosure, the light emitting layer further comprising a dopant material comprising at least one selected from Ir(ppy)3 and Ir(ppy)2 (acac). Thereby, the performance of the organic light emitting diode can be further improved.

According to embodiments of the present disclosure, the organic light emitting diode further comprising at least one of: a hole injection layer located between the anode and the light-emitting layer; a hole transport layer located on a side of the hole injection layer away from the anode; a light-emitting auxiliary located on a side of the hole transport layer away from the hole injection layer, the light emitting layer being located on a side of the light-emitting auxiliary away from the hole transport layer; a hole blocking layer located on a side of the light emitting layer away from the light-emitting auxiliary; an electron transport layer located on a side of the hole blocking layer away from the light emitting layer; and an electron injection layer located on a side of the electron transport layer away from the hole blocking layer. Thereby, the performance of the organic light emitting diode can be further improved.

In another aspect of the present disclosure, the present disclosure proposes a method for manufacturing an organic light emitting diode according to any one of claims 1 to 10 comprising: forming an anode; forming a light emitting layer on a side of the anode by evaporation; and forming a cathode on a side of the light emitting layer away from the anode. The organic light emitting diode described above can be obtain conveniently by the above method.

In yet another aspect of the present disclosure, the present disclosure proposes a display panel comprising: a substrate having thereon a plurality of the organic light emitting diodes according to any one of claims 1 to 10. Thus, the display panel has all the advantages of the organic light emitting diode described above and will not detailed here.

In further another aspect of the present disclosure, the present disclosure proposes a display device including the display panel described above. Thus, the display device has all the advantages of the display panel described above and will not be detailed here.

### BRIEF DESCRIPTION OF THE DRAWINGS

The above and/or additional aspects and advantages of the present disclosure will become apparent and readily appreciated from the following description of the embodiments taken in conjunction with the accompanying drawings, wherein:

FIG. 1 is a structural schematical view showing an organic light emitting diode according to an embodiment of the present disclosure;

FIG. 2 is a structural schematical view showing an organic light emitting diode according to another embodiment of the present disclosure.

### DETAILED DESCRIPTION OF THE EMBODIMENTS

Reference will now be made in detail to embodiments of the present disclosure, examples of which are illustrated in the accompanying drawings, in which same or similar reference numerals refer to same or similar elements or elements having same or similar functionality throughout the present disclosure. The embodiments described below with reference to the accompanying drawings are illustrative only and should not be taken as limiting the present disclosure.

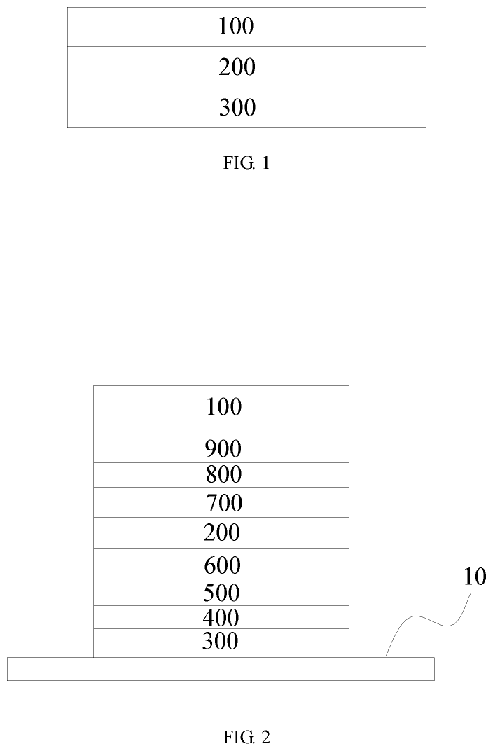

In one aspect of the present disclosure, the present disclosure proposes an organic light emitting diode. Referring to FIG. 1, the organic light emitting diode comprises an anode 300, a light emitting layer 200 and a cathode 100, where the light emitting layer 200 contains a dopant material and at least two kinds of host materials, and the light emitting layer has a horizontal alignment factor not less than 65%. Thus, the organic light emitting diode can have a higher external quantum efficiency.

For ease of understanding, a principle that the organic light emitting diode can achieve the above beneficial effects is briefly described below.

A light-emitting layer, in which an organic semiconductor material is employed, contains a host material and an acceptor material, and the host material is sensitized by using a dopant material so as to achieve a light emitting function. An energy transition efficiency between the host material and the dopant material is a biggest factor affecting a final luminous efficiency, thus most research regarding increasing quantum efficiency has focused the host material and the dopant material. When multiple host materials are employed in the light emitting layer, an energy transition efficiency between the host materials is also important, and an improved luminous performance can be achieved by adjusting a matching level of energy levels of HOMO (highest occupied orbital), LUMO (lowest empty orbital), T1 (triplet) between the multiple host materials. However, the inventors have found that when two and more mixed host materials are employed, in addition to hole transport and electron transport characteristics of material components, a horizontal alignment factor of the host materials has a significant impact on the luminous efficiency. Specifically, by increasing the horizontal alignment factor of each molecule, for example, adjusting the horizontal alignment factor (or called horizontal alignment ratio) of molecules of the host material with hole transport characteristics, the hole transport characteristics of the host material can be increased, and the horizontal alignment factor of molecules of the host material with electron transport characteristics can be adjusted correspondingly. Taking dopant materials as an example, the inventors found that Ir(ppy)₃ with a horizontal alignment ratio of 66 to 69% has an external quantum efficiency (EQE) of about 18.3%, while Ir(ppy)₂ (acac) with a horizontal alignment ratio of 77% has an EQE up to about 21.7%. It can be seen that EQE light extractions will be vary for different horizontal alignment ratios. With a direction parallel to the substrate and the anode of the LED being a horizontal direction, the EQE light extraction can be improved when the molecules are aligned horizontally rather than vertically. With only doping materials containing Ir compounds, the increasing of the horizontal alignment factor will result in an increase of a light extraction amount of the device above 18%. Thus, similarly, the increasing of the horizontal alignment factor of the host material and the light-emitting layer will also result in an improved device performance. Furthermore, the inventors have found that, once the horizontal alignment factor is increased, a ratio of horizontal arrangements between molecules of the organic semiconductor material becomes higher, with face to face arrangements being formed between molecules, and thus intermolecular energy transition is more favorable to improve the performance of the organic light emitting diode.

Specific types of host materials described above are not particularly limited according to embodiments of the present disclosure and may be selected by those skilled in the art according to actual needs. For example, the host material is an organic semiconductor material. Thereby, the performance of the organic light emitting diode can be further improved. Specifically, the host material may be a small molecule material, that is, an organic with a molecular weight below 1000.

According to embodiments of the present disclosure, the host materials may be of two types, and particularly may include a hole transporting host material and an electron transporting host material. Also, each of the hole transporting host material and the electron transporting host material has a horizontal alignment factor not less than 65%. Thus, the performance of the organic light emitting diode can be further improved to have higher external quantum efficiency.

Specific types of the host materials are not particularly limited according to embodiments of the present disclosure and may be selected by those skilled in the art according to actual needs, such as phosphorescent materials. In particular, the host materials described in the present disclosure can include at least one selected from a group consisting of Carbazole, Dibenzo furan, Dibenzo Thiophene, Indenlocarbazole, Indocarbazole, Benzofurazarbazole, Benzothiophene, Acridine, Tris-Indolobenzene, and derivatives and thickens thereof. Thereby, the performance of the organic light emitting diode can be further improved.

It is to be noted that, the derivatives described in the present disclosure may be the compounds above described with a plurality of substituted groups, and the substituted groups may be saturated or unsaturated alkyl groups with 1-6 C, or may be heteroatom-containing substituted groups such as amino, hydroxyl, carboxyl, and the like. For example, the derivatives of the above compounds may also have one or more phenyl substituted groups. The thickens of the compounds above described refer to a compound composed of a plurality of edge-shared aromatic rings comprising the compounds above described. For example, it may be a benzocarbazole or the like.

According to embodiments of the disclosure, the light emitting layer 200 may further include one or more acceptor materials. The type of the acceptor materials is not particularly limited and may be selected by those skilled in the art depending on the particular type and the energy level of the host materials. For example, the acceptor material may comprise at least one selected from a group consisting of Carbazole, Dibenzo furan, Dibenzo Thiophene, Indenlocarbazole, Indocarbazole, Benzofurazarbazole, Benzothiophene, Acridine, Tris-Indolobenzene, Pyridine, Pyrimidine, Aziner, Diphenylborane and derivatives and thickens thereof. Thereby, the performance of the organic light emitting diode can be further improved.

According to some embodiments of the present disclosure, the light-emitting layer 200 may include two types of host materials. The volume ratio of the two types of host materials is 9:1 to 1:9. For example, in particular, the volume ratio may be 5:1, 2:1, 1:1, 1:3, 1:5, and the like. Thereby, the performance of the organic light emitting diode can be further improved.

According to embodiments of the present disclosure, a first host material may be an indenocarbazole triazine compound and a second host material may be a bicarbazole compound. Thereby, the performance of the organic light emitting diode can be further improved. More specifically, the volume ratio of the two types of host materials may be 1:1. Thereby, the performance of the organic light emitting diode can be further improved.

According to embodiments of the present disclosure, the light-emitting layer 300 may further include one or more dopant materials therein. Specific types of the dopant materials are not particularly limited, and for example, an Ir containing compound may be selected. Specifically, the dopant material may comprise at least one selected from Ir(ppy)₃ and Ir(ppy)₂ (acac). Thereby, the performance of the organic light emitting diode can be further improved.

According to embodiments of the present disclosure, to further improve the performance of the organic light emitting diode, referring to FIG. 2, the organic light emitting diode may further include a structure such as a hole injection layer 400, in particular, the hole injection layer 300 may be located between the anode 300 and the light emitting layer 200, in particular, on a side of the anode 300 away from a substrate 10. A hole transport layer 500 may be located on a side of the hole injection layer 400 away from the anode 300, a light-emitting auxiliary layer 600 may be on a side of a hole transport layer 500 away from the hole injection layer 400, and the light-emitting layer 300 may be located on a side of the light-emitting auxiliary layer 600 away from the hole transport layer 500. A hole blocking layer 700 may be on a side of the light-emitting layer 300 away from the light-emitting auxiliary layer 600, and an electron transport layer 800 may be located on a side of the hole blocking layer 700 away from the light-emitting layer 300. An electron injection layer 900 is located on a side of the electron transport layer 800 away from the hole blocking layer 700, and the cathode 100 may be located on a side of the electron injection layer 900 away from the electron transport layer 800. Thereby, the performance of the organic light emitting diode can be further improved.

In another aspect of the present disclosure, the present disclosure provides a method of manufacturing the organic light emitting diode as described above, the method comprising the steps of forming an anode, forming a light emitting layer on a side of the anode by evaporating and forming a cathode on a side of the light emitting layer away from the anode. The method can obtain the organic light emitting diodes described above in a convenient way.

In particular, the anode may be formed of a metal or an alloy or a semiconductor oxide such as ITO. The anode may be formed on a substrate including but not limited to glass by sputtering. The structure comprising the light-emitting layer and the hole-injecting layer and the like described above may be formed by vacuum evaporation, the cathode may be formed from a semiconductor oxide such as ITO and may be formed by sputtering disposition too. When the light emitting layer described above in the present disclosure is formed, a light emitting layer having two or more host materials as well as an acceptor material and a dopant material can be formed by adjusting evaporation materials.

In yet another aspect of the present disclosure, the present disclosure proposes a display panel comprising a substrate having a plurality of organic light emitting diodes thereon, the organic light emitting diodes being as previously described. Thus, the display panel has all the advantages of the organic light emitting diode described above, and is not detailed here.

In yet another aspect of the present disclosure, the present disclosure proposes a display device including the display panel. Thus, the display device has all the advantages of the display panel described above, which will not be detailed here.

While the present disclosure is described with specific examples below, it will be understood by those skilled in the art that the following specific examples are intended for illustration purposes only and are not intended to limit the scope of the present disclosure in any way. Additionally, in the following examples, materials and devices employed are commercially available unless specifically stated otherwise. If in the following examples, specific processing conditions and processing methods are not explicitly described, processes may be performed using conditions and methods known in the art.

### Embodiment 1

Organic light emitting diodes are formed on glass substrates, and their structures are as follows.

The anode/the hole injection layer (HATCN) 10 nm/the hole transport layer (NPB) 70 nm/the light-emitting auxiliary layer (EB1) 10 nm/the light emitting layer (with Ir(ppy)₃ (10%)) 30 nm/the hole blocking layer (HB1) 5 nm/the electron transport layer (ET1+Liq) 30 nm/the electron injection layer (LiF) 1 nm/Al 200 nm.

The anode was ITO (Indium Tin Oxide) and had a thickness of 1000 Angstrom and was washed a total of 3 times for 30 minutes in a distilled water ultrasonic washer. After rinsing with distilled water, the anode was baked in a high temperature oven at 100° C. for 1 hour. Next, after cleaning in an Ozone washer for 3 minutes, the anode war transferred to a vacuum evaporation machine for evaporation of the layers.

The light-emitting layer comprises a first host material and a second host material in a volume ratio of 1:1. The first host material has a structure as shown by formula (1):

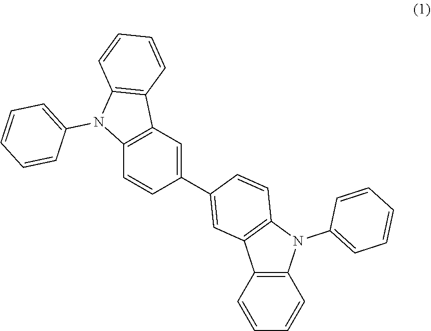 [SMILES: c1ccc(-n2c3ccccc3c3cc(-c4ccc5c(c4)c4ccccc4n5-c4ccccc4)ccc32)cc1]

The second host material has a structure as shown by formula (2):

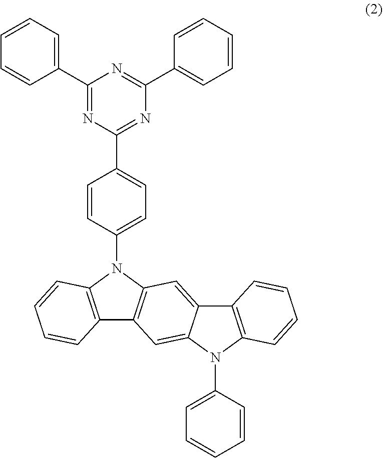 [SMILES: c1ccc(-c2nc(-c3ccccc3)nc(-c3ccc(-n4c5ccccc5c5cc6c(cc54)c4ccccc4n6-c4ccccc4)cc3)n2)cc1]

### Comparison Example 1

The comparison example 1 differs from the embodiment 1 in that, the host material is a compound shown by formula (3) below, and other parameters of the comparison example 1 are identical to those of the embodiment 1:

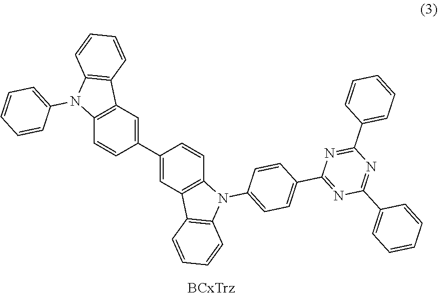 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

### Comparison Example 2

The comparison example 2 differs from the embodiment 1 in that, the host material is a compound shown by formula (4) below, and other parameters of the comparison example 2 are identical to those of the embodiment 1:

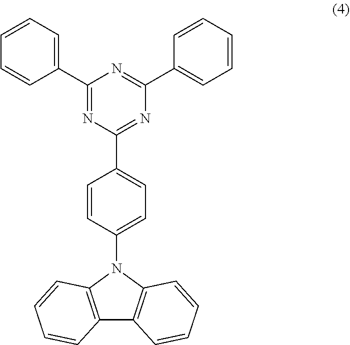 [SMILES: c1ccc(-c2nc(-c3ccccc3)nc(-c3ccc(-n4c5ccccc5c5ccccc54)cc3)n2)cc1]

Testing Method

Related structures were fabricated on glass substrates and tested for PL luminous intensity according to angles. Comparative analysis was conducted for PL peaks with test angles between 40 and 80 degrees, and the performance of the organic light emitting diodes was tested for parameters shown in Table 2 below.

The relevant results are as follows:

TABLE 1

| Category | Horizontal alignment factor |
|---|---|
| Comparison Example 1 | 65% |
| Comparison Example 2 | 66% |
| Embodiment 1 | 80% |

TABLE 2

| | Turn-one | luminous | Chromatic |
|---|---|---|---|
| | voltage V | efficiency cd/A | coordinate |
| Category | (10 mA/cm²) | (10 mA/cm²) | (x, y) |
| Comparison | 4.8 | 16 | 0.35, 0.53 |
| Example 1 | | | |
| Comparison | 4.9 | 17 | 0.33, 0.61 |
| Example 2 | | | |
| Embodiment 1 | 4.0 | 26 | 0.34, 0.61 |

As can be seen from the above Tables 1 and 2, with the increase of the horizontal alignment factor, the device characteristics will be improved, especially in the luminance efficiency and voltage as compared to the existing levels. It can be seen from the above results that, in the Embodiment 1 with the higher horizontal alignment factor, the EQE, current efficiency, and power efficiency of the organic light emitting device are highest.

In the description of this specification, references to “one embodiment”, “another embodiment” and the like mean that a particular feature, structure, material, or characteristic described in connection with the embodiment is included in at least one embodiment of the present disclosure. In this specification, schematic representations of the above terms are not necessarily referring to the same embodiment or example. Furthermore, the described particular features, structures, materials, or characteristics may be combined in any suitable manner in any one or more embodiments or examples. Moreover, different embodiments or examples and features of different embodiments or examples described in this specification can be incorporated and combined by those skilled in the art without contradicting each other.

While embodiments of the present disclosure have been shown and described above, it should be understood that the above embodiments are exemplary and are not to be construed as limitations on the present disclosure, as changes, modifications, alternatives, and variations thereof may occur to those skilled in the art within the scope of the present disclosure.

1. An organic light emitting diode comprising:
an anode;
a light-emitting layer; and
a cathode,
wherein the light emitting layer has a dopant material and at least two types of host materials therein, and the light emitting layer has a horizontal alignment factor not less than 65%.

2. The organic light emitting diode according to claim 1, wherein
the host materials comprise a hole transporting host material and an electron transporting host material; and
each of the hole transporting host material and the electron transporting host material has a horizontal alignment factor not less than 65%.

3. The organic light emitting diode according to claim 1, wherein the host materials are an organic semiconductor material.

4. The organic light emitting diode according to claim 3, wherein the host materials comprise at least one selected from Carbazole, Dibenzo furan, Dibenzo Thiophene, Indenlocarbazole, Indocarbazole, Benzofurazarbazole, Benzothiophene, Acridine, Tris-Indolobenzene, and derivatives and thickens thereof.

5. The organic light emitting diode according to claim 1, wherein the light emitting layer further comprises an acceptor material comprising at least one selected from Carbazole, Dibenzo furan, Dibenzo Thiophene, Indenlocarbazole, Indocarbazole, Benzofurazarbazole, Benzothiophene, Acridine, Tris-Indolobenzene, Pyridine, Pyrimidine, Aziner, Diphenylborane and derivatives and thickens thereof.

6. The organic light emitting diode according to claim 1, wherein
the light emitting layer comprises two host types of materials, and
a volume ratio between the two types of host materials is 9:1 to 1:9.

7. The organic light emitting diode according to claim 6, wherein
the first host material is Indenlocarbazole triazine and
the second host material is Bicarbazole.

8. The organic light emitting diode according to claim 7, wherein a volume ratio of the first host material to the second host material in the light emitting layer is 1:1.

9. The organic light emitting diode according to claim 1, wherein the dopant material comprising at least one selected from Ir(ppy)₃ and Ir(ppy)₂ (acac).

10. The organic light emitting diode according to claim 1, further comprising at least one of:
a hole injection layer located between the anode and the light-emitting layer;
a hole transport layer located on a side of the hole injection layer away from the anode;
a light-emitting auxiliary located on a side of the hole transport layer away from the hole injection layer, the light emitting layer being located on a side of the light-emitting auxiliary away from the hole transport layer;
a hole blocking layer located on a side of the light emitting layer away from the light-emitting auxiliary;
an electron transport layer located on a side of the hole blocking layer away from the light emitting layer; and
an electron injection layer located on a side of the electron transport layer away from the hole blocking layer.

11. A method for manufacturing an organic light emitting diode according to claim 1 comprising:
forming an anode;
forming a light emitting layer on a side of the anode by evaporation; and
forming a cathode on a side of the light emitting layer away from the anode.

12. A display panel comprising:
a substrate having thereon a plurality of the organic light emitting diodes according to claim 1.

13. A display device comprising the display panel of claim 12.

14. The organic light emitting diode according to claim 1, wherein the hose material has a molecular structure combining a donor compound with an acceptor compound.

15. The organic light emitting diode according to claim 14, wherein the donor compound comprises at least one selected from Carbazole, Dibenzo furan, Dibenzo Thiophene, Indenlocarbazole, Indocarbazole, Benzofurazarbazole, Benzothiophene, Acridine, Tris-Indolobenzene, and derivatives and thickens thereof.

16. The organic light emitting diode according to claim 14, wherein the acceptor compound comprises at least one selected from Carbazole, Dibenzo furan, Dibenzo Thiophene, Indenlocarbazole, Indocarbazole, Benzofurazarbazole, Benzothiophene, Acridine, Tris-Indolobenzene, Pyridine, Pyrimidine, Aziner, Diphenylborane and derivatives and thickens thereof.

17. The display panel according to claim 12,
the host materials comprise a hole transporting host material and an electron transporting host material; and
each of the hole transporting host material and the electron transporting host material has a horizontal alignment factor not less than 65%.

18. The display panel according to claim 12, wherein the organic light emitting diode further comprises at least one of:
a hole injection layer located between the anode and the light-emitting layer;
a hole transport layer located on a side of the hole injection layer away from the anode;
a light-emitting auxiliary located on a side of the hole transport layer away from the hole injection layer, the light emitting layer being located on a side of the light-emitting auxiliary away from the hole transport layer;
a hole blocking layer located on a side of the light emitting layer away from the light-emitting auxiliary;
an electron transport layer located on a side of the hole blocking layer away from the light emitting layer; and
an electron injection layer located on a side of the electron transport layer away from the hole blocking layer.
